(19) United States
(12) Patent Application Publication
(10) Pub. No.: US 2012/0156887 A1
(43) Pub. Date: Jun. 21, 2012

(54) VACUUM PROCESSING APPARATUS AND VACUUM PROCESSING METHOD

(76) Inventors: Youhei Ono, Shizuoka (JP); Masaaki Kawana, Shizuoka (JP); Yutaka Miura, Shizuoka (JP)

(21) Appl. No.: 13/392,010

(22) PCT Filed: Aug. 24, 2010
(86) PCT No.: PCT/JP2010/064220

§ 371 Date: Feb. 23, 2012

(30) Foreign Application Priority Data
Aug. 27, 2009 (JP) 2009-197399

(51) Int. Cl. H01L 21/306; H01L 21/3065

(52) U.S. Cl. 438/706; 156/345.27; 257/E21.215

(57) ABSTRACT

A vacuum processing apparatus, comprising: a processing chamber 3 in which an object to be processed is placed and a predetermined vacuum state is formed; a first processing gas introducing means 12 for converting a first processing gas into a radical state and introducing the resulting first processing gas in the radical state into the processing chamber through first processing gas introducing ports which open to the interior of the processing chamber; a second processing gas introducing means 15 for introducing a second processing gas, which is reactive with the first processing gas in the radical state, into the processing chamber through second processing gas introducing ports which open to the interior of the processing chamber; a temperature controlling means for controlling the temperature within the processing chamber 3 to a first temperature-controlled state, in which the first processing gas in the radical state and the second processing gas process the surface of the object to be processed, thereby producing a reaction product, and to a second temperature-controlled state in which the resulting reaction product is sublimated and removed; and an inert gas introducing means for introducing an inert gas into the processing chamber 3 through the processing gas introducing ports 12 when the temperature controlling means controls the temperature within the processing chamber to the second temperature-controlled state.

### TECHNICAL FIELD

This invention relates to a vacuum processing apparatus and a vacuum processing method for performing processing, for example, etching, in a processing chamber in a vacuum state.

### PRIOR ART

In a process for producing a semiconductor device, it is necessary, for example, to remove a native oxide film (e.g., SiO₂) formed on a wafer at the bottom of a contact hole of a semiconductor substrate (semiconductor wafer). As a technology for removing the native oxide film, various proposals using hydrogen in a radical state (H*) and NF₃ gas have been made (see, for example, Patent Document 1).

The technology disclosed in Patent Document 1 is a technology which comprises introducing gases through a first nozzle portion for introducing H gas, which has been converted into radicals by a plasma using microwaves, and through second nozzle portions for introducing NF₃, in a first gas introducing section within a processing chamber brought to a predetermined vacuum state, the second nozzle portions being provided at a position within the processing chamber where the first nozzle portion is interposed, thereby reacting these gases with an oxidized surface of a silicon wafer (SiO₂) disposed in an atmosphere in a predetermined vacuum state to form a reaction product (NH₄) ₂SiF₆. Then, the processing chamber is heated to control the silicon substrate to a predetermined temperature, whereby (NH₄)₂SiF₆ is sublimated to remove (etch away) the native oxide film on the surface of the silicon substrate.

In accordance with demands for the mass production and cost reduction of semiconductor devices in recent years, it is required to carry out the above-mentioned processing with efficiency and at a low cost in a vacuum apparatus for the processing as well. with the above conventional processing, however, there has been the problem that particles occur when (NH₄)₂SiF₆, the reaction product, is sublimated to remove (etch away) the native oxide film on the surface of the silicon substrate. The same has been true when a purge gas is introduced through the second nozzle portions during the sublimation of the reaction product. Furthermore, demand is growing for the cleanliness of the surface of the silicon wafer (single crystal silicon, polysilicon) deprived of the native oxide film. Further cleanness of the silicon surface after removal of the native oxide film is demanded under these circumstances.

### PRIOR ART DOCUMENTS

### Patent Documents

[Patent Document 1] JP-A-2005-203404

### SUMMARY OF THE INVENTION

### Problems to be Solved by the Invention

The present invention has been accomplished in light of the above-described situations. It is an object of the present invention to provide a vacuum processing apparatus which can remove a native oxide film with efficiency and at low cost. It is another object of the invention to provide a vacuum processing apparatus which can further clean the surface of a substrate after the native oxide film is removed.

### Means for Solving the Problems

A first aspect of the present invention for attaining the above objects is a vacuum processing apparatus comprising: a processing chamber in which an object to be processed is placed and a predetermined vacuum state is formed; a first processing gas introducing means for converting a first processing gas into a radical state and introducing the resulting first processing gas in the radical state into the processing chamber through first processing gas introducing ports which open to the interior of the processing chamber; a second processing gas introducing means for introducing a second processing gas, which is reactive with the first processing gas in the radical state, into the processing chamber through second processing gas introducing ports which open to the interior of the processing chamber; a temperature controlling means for controlling the temperature within the processing chamber to a first temperature-controlled state, in which the first processing gas in the radical state and the second processing gas process the surface of the object to be processed, thereby producing a reaction product, and to a second temperature-controlled state in which the resulting reaction product is sublimated and removed; and an inert gas introducing means for introducing an inert gas into the processing chamber through the first processing gas introducing ports when the temperature controlling means controls the temperature within the processing chamber to the second temperature-controlled state.

According to the above-mentioned first aspect, in the second temperature-controlled state in which the resulting reaction product is sublimated and removed, the inert gas is introduced through the first processing gas introducing ports, whereby there is a decrease in the amount of the sublimate of the reaction product passing through the first processing gas introducing ports and diffusing into the first processing gas introducing means for converting the first processing gas into the radical state. Consequently, efficient processing can be achieved, and the contamination of the first processing gas introducing system can also be prevented.

A second aspect of the present invention is the vacuum processing apparatus according to the first aspect, wherein the inert gas introducing means is equipped with introduction controlling means for controlling an introduction status of the inert gas through the first processing gas introducing ports so as to prevent a sublimate of the reaction product from passing and diffusing through the processing gas introducing ports.

According to the above-mentioned second aspect, the introduction controlling means controls the introduction status of the inert gas, thereby reliably preventing the diffusion of the sublimate into the first processing gas introducing means via the first processing gas introducing ports.

A third aspect of the present invention is the vacuum processing apparatus according to the second aspect, wherein the introduction controlling means controls the introduction status of the inert gas such that a Peclet number representing a state of a difference between an introduction flux of the inert gas introduced and a diffusion flux of the sublimate of the reaction product becomes 10 or more.

According to the above-mentioned third aspect, the introduction status of the inert gas is controlled such that a Peclet number which is the ratio between the introduction flux of the inert gas introduced and the diffusion flux of the sublimate of the reaction product becomes 10 or more. Thus, the diffusion of the sublimate via the processing gas introducing ports is prevented even more reliably.

A fourth aspect of the present invention is the vacuum processing apparatus according to any one of the first to third aspects, wherein the inert gas introducing means is adapted to introduce the inert gas via the first gas introducing means.

According to the above-mentioned fourth aspect, the inert gas is introduced via the first gas introducing means. Thus, the diffusion of the sublimate through the first gas introducing ports is prevented.

A fifth aspect of the present invention is the vacuum processing apparatus according to any one of the first to fourth aspects, wherein the first gas introducing means is adapted to equip a first gas introducing path, which communicates with the first gas introducing ports, with a plasma generating section, and convert the introduced first processing gas into a plasma state in the plasma generating section.

According to the above-mentioned fifth aspect, the first processing gas introduced into the first gas introducing path is turned into the plasma state in the plasma generating section, and introduced through the first gas introducing ports.

A sixth aspect of the present invention is the vacuum processing apparatus according to any one of the first to fifth aspects, wherein the first processing gas is a gas for generating H radicals, the second processing gas is a gas for generating at least NHₓF_{y}, and the object to be processed is a silicon substrate.

According to the above-mentioned sixth aspect, the first processing gas, the second processing gas, and the native oxide film on the surface of the silicon substrate (silicon wafer) are reacted to form a reaction product, and the silicon wafer is controlled to a predetermined temperature to sublimate the reaction product, whereby the native oxide film on the surface of the silicon wafer can be removed.

A seventh aspect of the present invention is the vacuum processing apparatus according to the sixth aspect, wherein the first processing gas is at least one of NH₃ and H₂ and N₂, and the second processing gas is NF₃.

According to the above-mentioned seventh aspect, NHₓF_{y} produced by the reaction of H radicals from NH₃ and H₂ with NF₃ as the second processing gas is reacted with the native oxide film on the surface of the silicon substrate (silicon wafer) to form a reaction product, and the silicon wafer is controlled to a predetermined temperature to sublimate the reaction product, whereby the native oxide film on the surface of the silicon wafer is removed.

An eighth aspect of the present invention is the vacuum processing apparatus according to the sixth or seventh aspect, further comprising auxiliary gas introducing means for introducing an auxiliary processing gas in a radical state into the processing chamber, and control means for controlling an introduction status of the auxiliary processing gas introduced from the auxiliary gas introducing means and the second processing gas introduced from the second gas introducing means, thereby removing a surface layer of the silicon substrate, which has been deprived of a native oxide film by processing with the processing gases, by a predetermined thickness by the auxiliary processing gas and the second processing gas.

According to the above-mentioned eighth aspect, after the native oxide film of the silicon substrate is removed, the control means introduces the auxiliary processing gas from the auxiliary gas introducing means so that the control means allows the auxiliary processing gas to remove, by a predetermined thickness, the surface layer of the silicon substrate after removal of the native oxide film. Hence, oxygen in the surface of the substrate after removal of the native oxide film can be reliably removed using the processing apparatus for removing the native oxide film.

A ninth aspect of the present invention is the vacuum processing apparatus according to the eighth aspect, wherein the first gas introducing means concurrently serves as the auxiliary gas introducing means.

According to the above-mentioned ninth aspect, facilities can be simplified, because the first gas introducing means concurrently serves as the auxiliary gas introducing means.

A tenth aspect of the present invention is the vacuum processing apparatus according to the eighth or ninth aspect, wherein the control means applies the auxiliary processing gas and the second processing gas to a surface of the silicon substrate deprived of the native oxide film, thereby removing a silicon layer of the silicon substrate by the predetermined thickness.

According to the above-mentioned tenth aspect, after removal of the native oxide film of the silicon substrate, the surface layer of the silicon substrate is removed by a predetermined thickness. In this manner, after the native oxide film is removed, oxygen in the surface of the substrate can be removed even more reliably.

An eleventh aspect of the present invention is a vacuum processing method, comprising: introducing a first processing gas in a radical state into a processing chamber, in which an object to be processed is placed and a predetermined vacuum state is formed, through first processing gas introducing ports, and also introducing a second processing gas, which is reactive with the first processing gas in the radical state, into the processing chamber through second processing gas introducing ports; and controlling a temperature within the processing chamber to a first temperature-controlled state, in which the first processing gas in the radical state and the second processing gas process a surface of the object to be processed, thereby producing a reaction product, and then to a second temperature-controlled state in which the resulting reaction product is sublimated and removed, while introducing an inert gas into the processing chamber through the first processing gas introducing ports when controlling the temperature within the processing chamber to the second temperature-controlled state.

According to the above-mentioned eleventh aspect, in the second temperature-controlled state in which the resulting reaction product is sublimated and removed, the inert gas is introduced through the first processing gas introducing ports, whereby there is a decrease in the amount of the sublimate of the reaction product passing through the first processing gas introducing ports and diffusing into the first processing gas introducing means for converting the first processing gas into the radical state. Consequently, efficient processing can be achieved, and the contamination of the first processing gas introducing system can also be prevented.

### Effects of the Invention

The present invention is the vacuum processing apparatus including the temperature controlling means for controlling the temperature within the processing chamber to the first temperature-controlled state, in which the processing gases process the surface of the object to be processed, thereby producing a reaction product, and to the second temperature-controlled state in which the resulting reaction product is sublimated and removed, wherein in the second temperature-controlled state in which the resulting reaction product is sublimated and removed, the inert gas is introduced through the first processing gas introducing ports. Thus, there is a decrease in the amount of the sublimate of the reaction product passing through the first processing gas introducing ports and diffusing into the first processing gas introducing system. Consequently, efficient processing can be achieved, and contamination of the processing gas introducing system can also be prevented.

Using the processing apparatus for removing the native oxide film, oxygen in the surface of the substrate can be removed reliably after the native oxide film is removed.

### BRIEF DESCRIPTION OF THE DRAWINGS

FIG. 1 is a general configurational drawing of a vacuum processing apparatus according to a first embodiment of the present invention.

FIG. 2 is a schematic configurational drawing of the processing apparatus.

FIG. 3 is a conceptual view representing the status of processing gases when removing a native oxide film.

FIGS. 4(a) to 4(d) are explanation drawings of a process for removal of the native oxide film.

FIG. 5 is a graph showing the situation of removal of the native oxide film.

FIG. 6 is a conceptual view showing the state of fluxes of gases at a first gas introducing port.

FIG. 7 is a conceptual view representing the status of processing gases when removing a silicon layer.

FIGS. 8(a) to 8(c) are explanation drawings of a process for removal of the silicon layer.

FIG. 9 is a graph showing the situation of removal of the silicon layer.

FIG. 10 is a time-chart representing changes over time in the processing gases for the removal of the native oxide film and the removal of the silicon layer.

FIG. 11 is a schematic view showing a concrete use.

FIGS. 12(a) and 12(b) are views showing the results of a test example.

### MODE FOR CARRYING OUT THE INVENTION

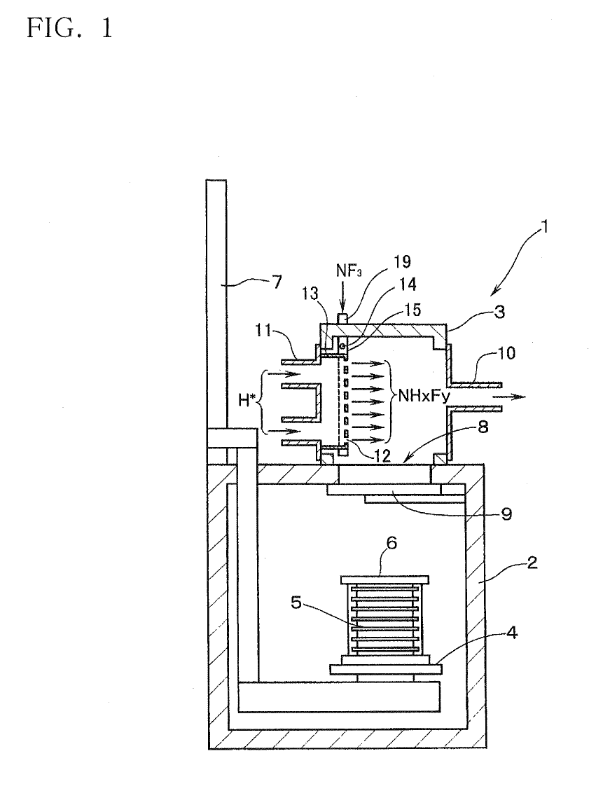

A first embodiment of the present invention will now be described based on FIGS. 1 to 11.

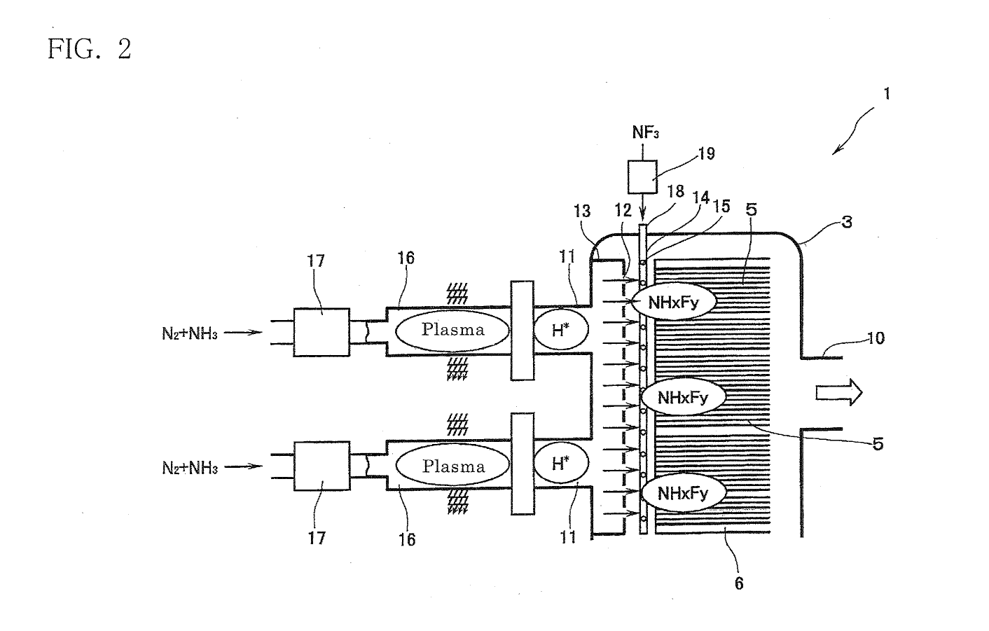

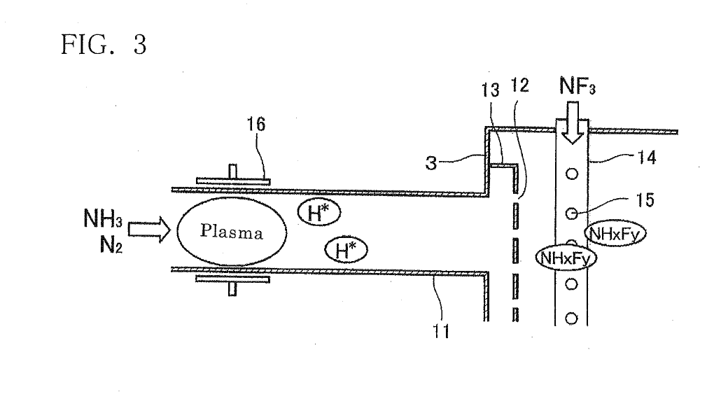

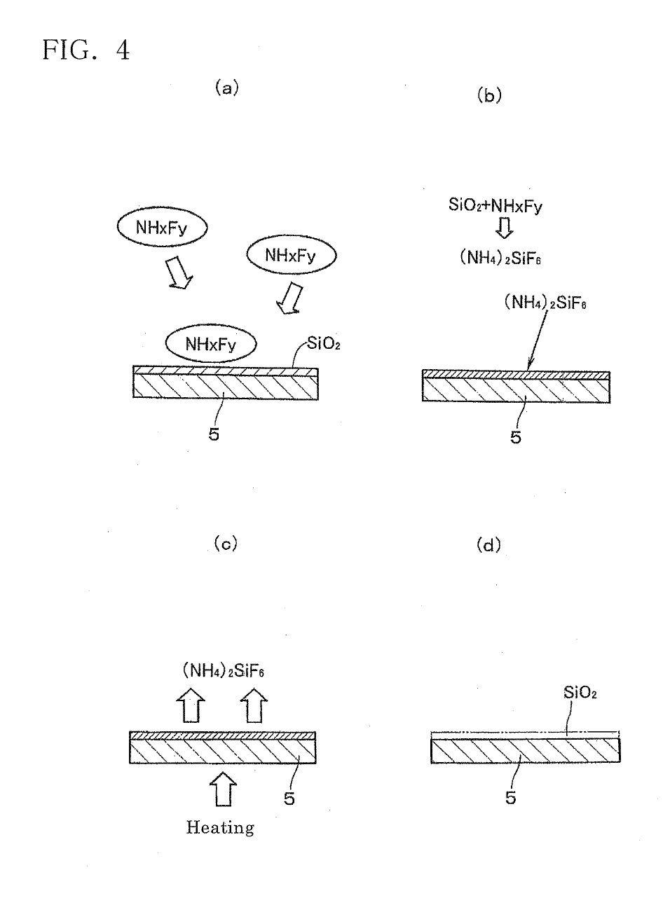

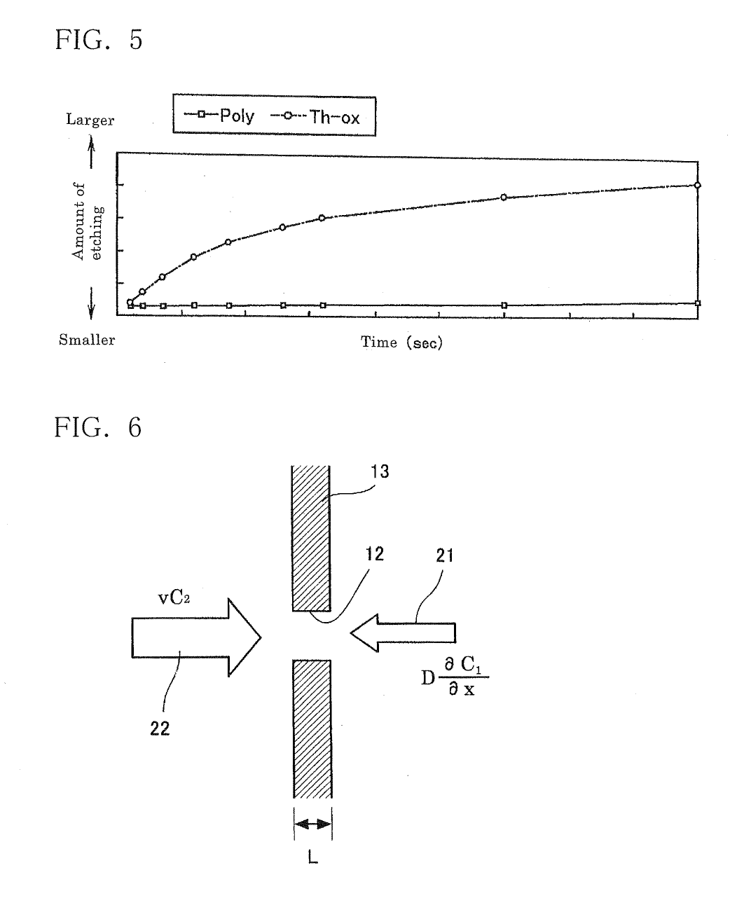

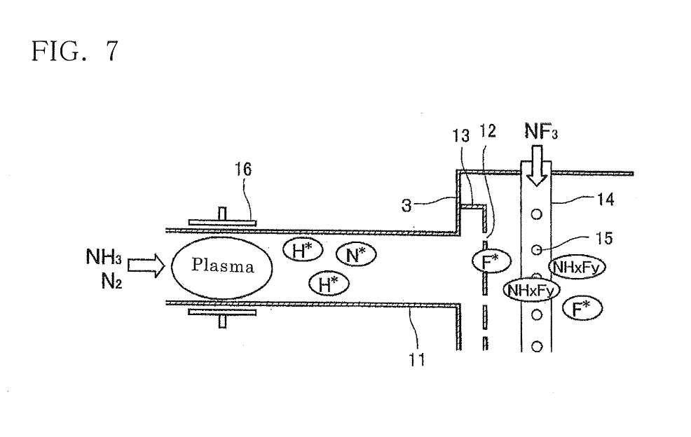

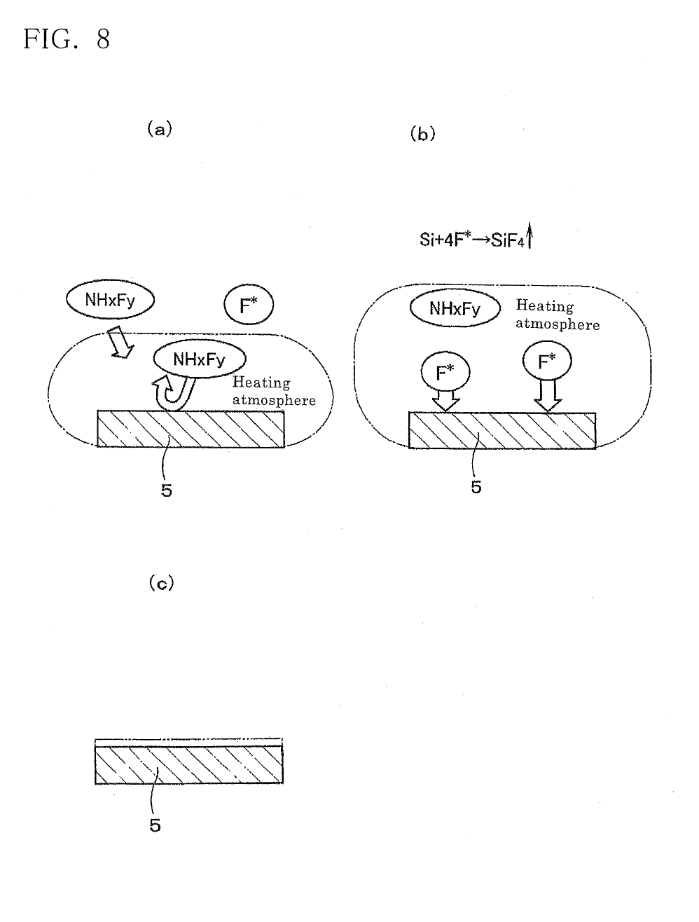

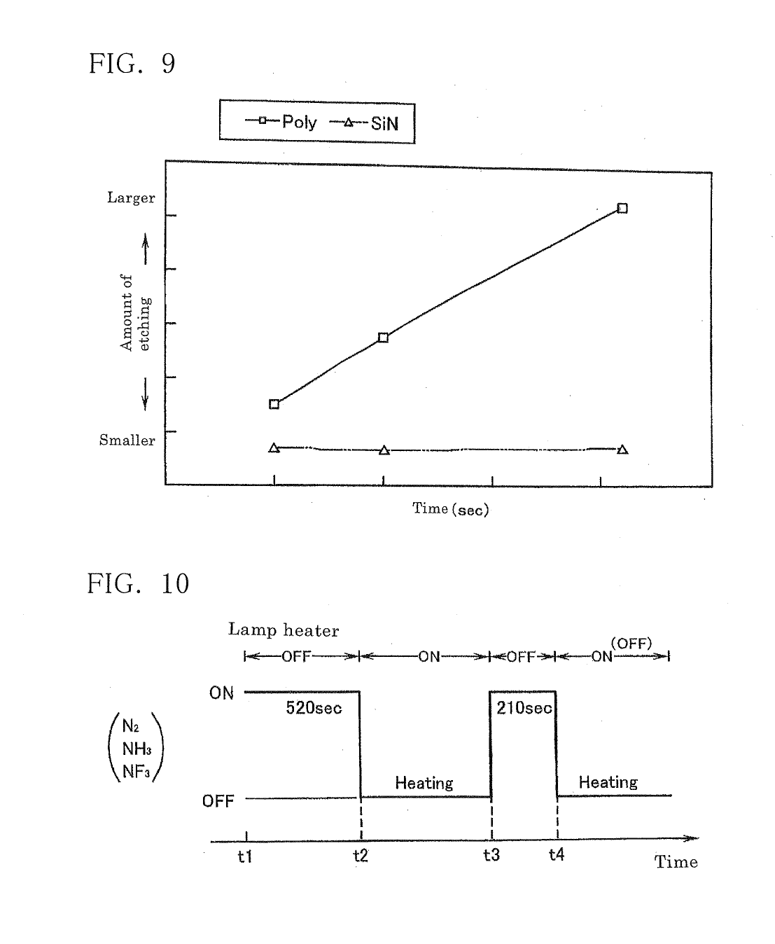

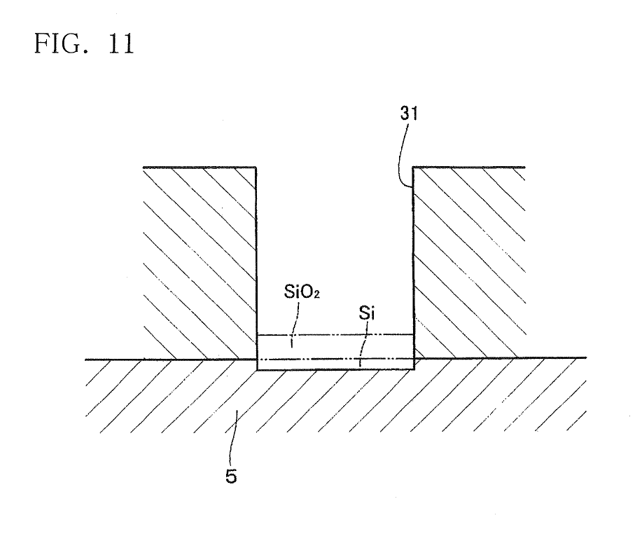

FIG. 1 illustrates the general configuration of a vacuum processing apparatus according to the first embodiment of the present invention. FIG. 2 illustrates the schematic configuration of the processing apparatus. FIG. 3 illustrates a concept representing the status of processing gases when removing a native oxide film. FIGS. 4(a) to 4(d) illustrate a process for removal of the native oxide film. FIG. 5 shows a graph representing the situation of removal of the native oxide film. FIG. 6 illustrates a concept showing the state of fluxes of gases at a first gas introducing port. FIG. 7 illustrates a concept representing the status of processing gases when removing a silicon layer. FIGS. 8(a) to 8(c) illustrate a process for removal of the silicon layer. FIG. 9 shows a graph illustrating the situation of removal of the silicon layer. FIG. 10 shows changes over time in the processing gases for the removal of the native oxide film and the removal of the silicon layer. FIG. 11 shows an outline representing a concrete use.

The configuration of the vacuum processing apparatus will be described based on FIGS. 1 and 2.

As shown in FIG. 1, a vacuum processing apparatus (etching apparatus) 1 is equipped with a charge/withdrawal vessel 2 connected to a vacuum evacuation system, and a vacuum processing vessel 3 as a processing chamber is provided above the charge/withdrawal vessel 2. A turn table 4 rotatable at a predetermined speed is provided inside the charge/withdrawal vessel 2, and a boat 6 holding silicon a substrate 5 as a substrate is supported on the turn table 4. A plurality of (e.g., 50) of the silicon substrates 5 are accommodated in the boat 6, and the plurality of silicon substrates 5 are arranged parallel to each other with predetermined spacing.

Silicon of the silicon substrate 5 maybe single crystal silicon or polycrystalline silicon (polysilicon) and, hereinafter, will simply be referred to as silicon. If the silicon substrate of polysilicon is applied, therefore, etching of a silicon layer to be described later is etching of a polysilicon layer.

A feed screw 7 extending in a vertical direction is provided above the charge/withdrawal vessel 2, and the turn table 4 acts to be raised and lowered by the driving of the feed screw 7. The charge/withdrawal vessel 2 and the vacuum processing vessel 3 have interiors communicating with each other via a communicating port 8, and are atmospherically isolated from each other by a shutter means 9. Upon the opening or closing of the shutter means 9 and the raising or lowering of the turn table 4, the boat 6 (silicon substrates 5) is delivered from and received by the charge/withdrawal vessel 2 and the vacuum processing vessel 3.

In the drawings, the numeral 10 denotes a discharge section for performing vacuum evacuation of the interior of the vacuum processing vessel 3.

In a side part of the vacuum processing vessel 3, first gas introducing paths 11 for introducing hydrogen in a radical state (H radicals: H*) are provided at two locations. The two first gas introducing paths 11 communicate with a first shower nozzle 13, which extends in the vertical direction and has a plurality of first gas introducing ports 12 in the vertical direction, so that H radicals H* are introduced into the vacuum processing vessel 3 through the first gas introducing ports 12. On the other hand, a second shower nozzle 14 which introduces NF₃ as a second processing gas (processing gas) is provided inside the vacuum processing vessel 3 so that NF₃ is introduced into the vacuum processing vessel 3 through a plurality of second gas introducing ports 15 provided in the second shower nozzle 14 extending in the vertical direction. The H radicals H* introduced through the first gas introducing ports 12 and NF₃ introduced through the second gas introducing ports 15 are reacted to produce a precursor NHₓF_{y}, which serves as a processing gas, inside the vacuum processing vessel 3.

As shown in FIG. 2, plasma generating sections 16 are provided upstream of the respective first gas introducing paths 11. The plasma generating section 16 converts the processing gas into a plasma state by microwaves. The plasma generating section 16 communicating with the first gas introducing path 11 is supplied with NH₃ gas and N₂ gas, as a first processing gas, via a flow regulating means 17. In the plasma generating section 16, the NH₃ gas and the N₂ gas are turned into a plasma state to form H radicals H*, and the H radicals H* are introduced into the first gas introducing path 11. On the other hand, a second gas introducing path 18 communicating with the second shower nozzle 14 is supplied with NF₃ gas via a flow regulating means 19.

The first shower nozzle 13, the first gas introducing ports 12, and the flow regulating means 17 constitute a first gas introducing means, while the second shower nozzle 14, the second gas introducing path 18, and the flow regulating means 19 constitute a second gas introducing means.

In the present embodiment, the first gas introducing means concurrently serves as an inert gas introducing means. When the first gas introducing means functions as the inert gas introducing means, the plasma generating section 16 is stopped, the supply of the NH₃ gas is also stopped, and only the N₂ gas can be introduced via the flow regulating means 17. The N₂ gas is introduced via the first gas introducing ports 12 of the first shower nozzle 13.

The inert gas introducing means maybe provided separately from the first gas introducing means. For example, it is permissible to provide a flow path branching from the first gas introducing path 11 midway through it, such as the side downstream of the plasma generating section 16, via a switching means or the like, and to switch to the flow path at the time of inert gas introduction, and introduce the inert gas through the first gas introducing ports 12.

The vacuum processing vessel 3 is provided with a lamp heater (not shown) as a temperature controlling means, and the temperature inside the vacuum processing vessel 3, namely, the temperature of the silicon substrates 5, is controlled to a predetermined state by the lamp heater. The flow-through status of the processing gases by the flow regulating means 17, 19, and the operating state of the lamp heater are controlled, as appropriate, by a control device (not shown) as a control means.

In the above-described vacuum processing apparatus 1, the boat 6 holding the silicon substrates 5 is carried into the vacuum processing vessel 3 and, with the interior of the vacuum processing vessel 3 being kept in an airtight state, vacuum evacuation is performed so that a predetermined pressure is achieved.

Under a command from the control device, the processing gases (N₂ gas and at least one of NH₃ gas and H₂; and NF₃ gas) are introduced into the vacuum processing vessel 3 to react the processing gases with a native oxide surface (SiO₂) of each silicon substrate 5 disposed in an atmosphere in a predetermined vacuum state (i.e., adsorption reaction at a low temperature), whereby a reaction product (a compound of F_{y} and NHₓ {(NH₄)₂SiF₆}) is formed. After formation of the reaction product, the temperature controlling means actuates the lamp heater to control the silicon substrates 5 to a predetermined temperature and sublimate the reaction product ((NH₄)₂SiF₆), thereby removing (etching away) the native oxide film on the surface of each silicon substrate 5.

In the present embodiment, when the silicon substrates 5 are controlled to the predetermined temperature, the first gas introducing means is allowed to function as the inert gas introducing means. At this time, the plasma generating section 16 is stopped, the supply of the NH₃ gas is stopped, and only the N₂ gas is introduced via the flow regulating means 17. By this means, the sublimate of the reaction product is prevented from passing through the first gas introducing ports 12 and diffusing into the interiors of the first shower nozzle 13 and the first gas introducing paths 11. Details of this point will be presented later.

The native oxide film is removed by the above-mentioned two-stage processing, but to clean the surface of the silicon substrate 5 further, processing for etching away the silicon layer of a predetermined thickness on the surface of the silicon substrate 5 may be further performed.

Concretely, with the arrangement of the silicon substrates 5 deprived of the native oxide film being maintained, at least one of NH₃ gas and H₂ gas as well as N₂ gas, as an auxiliary processing gas, and NF₃ gas are introduced into the vacuum processing vessel 3 under a command from the control device. That is, the same processing gases as the processing gases used in etching the native oxide film are introduced to etch away the silicon layer of a predetermined thickness.

Etching of the native oxide film will be described based on FIGS. 3 to 5.

In a first step, as shown in FIG. 3, the interior of the vacuum processing vessel 3 is brought into a room-temperature state (first temperature-controlled state), NH₃ gas and N₂ gas are introduced from the first gas introducing path 11 via the flow regulating means 17, and H radicals H* are generated in the plasma generating section 16. The resulting H radicals H* are fed into the vacuum processing vessel 3 through the first gas introducing ports 12 of the first shower nozzle 13. Simultaneously, NF₃ gas is introduced into the vacuum processing vessel 3 through the second gas introducing ports 15 of the second shower nozzle 14 via the flow regulating means 19. The H radicals H* and the NF₃ gas are mixed and reacted to produce NHₓF_{y}.

That is, H*+NF₃→NHₓF_{y} (NH₄FH, NH₄FHF, etc.)

As shown in FIG. 4(a), NHₓF_{y} and the native oxide surface of the silicon substrate 5 (SiO₂) react to form (NH₄)₂SiF₆ which is a product from F_{y}, NHₓ and SiO₂.

That is, NHₓF_{y}+SiO₂→(NH₄)₂SiF₆+H₂O↑

After the reaction product by the first step is formed in abundance, the process shifts to a second step. In the second step, the vacuum processing vessel 3 is heated by the lamp heater (see FIG. 2) (i.e., second temperature-controlled state: e.g., 100° C. to 200° C.) to sublimate (NH₄) ₂SiF₆ and remove it from the surface of the silicon substrate 5, as shown in FIG. 4(c).

In this second step, the first gas introducing means is allowed to function as the inert gas introducing means. At this time, the plasma generating section 16 is stopped, the supply of the NH₃ gas is stopped, and only the N₂ gas is introduced via the flow regulating means 17. By this means, the sublimate of the reaction product is prevented from passing through the first gas introducing ports 12 and diffusing into the interiors of the first shower nozzle 13 and the first gas introducing paths 11.

In this manner, the first step and the second step are carried out to etch the surface of the silicon substrate 5 and remove (NH₄)₂SiF₆. By so doing, the native oxide film on the surface of the silicon substrate 5 is removed to provide a clean surface, as shown in FIG. 4(d). At this time, the native oxide film increases in the amount of etching in accordance with the etching time as indicated by circles ◯ in FIG. 5, whereas the silicon layer scarcely changes in the amount of etching with the passage of the etching time as indicated by squares □, showing that the silicon layer has not been etched away.

The effect of preventing diffusion in the first gas introducing ports 12 in the second step will be described by reference to FIG. 6.

FIG. 6 shows the state of fluxes of gases in each first gas introducing port 12, the numeral 21 denoting the flux of the sublimate of the reaction product, and the numeral 22 denoting the flux of nitrogen N₂ which is an inert gas. As illustrated in the drawing, the flux 21 is expressed as the product of D, which is the diffusion coefficient of the sublimate, and the concentration gradient ∂C₁/∂x, while the flux 22 is expressed as the product of the velocity of nitrogen and the concentration of nitrogen, C₂.

The ratio of the flux 21 to the flux 22 is preferably evaluated by the number of states called Peclet number Pe. The Peclet number Pe is represented by the following equation as the ratio of the rate of advection of flow to the rate of diffusion:

Pe=vL/D

In this equation, L denotes the representative length and, in this case, is the thickness of the first shower nozzle 13. In order to prevent the sublimate from passing through the first gas introducing port 12 and diffusing, the Peclet number Pe may be sufficiently greater than 1. The Peclet number Pe of 10 or more means that diffusion can theoretically be prevented nearly reliably. It goes without saying that with the Peclet number Pe of 50 or more, preferably 70 or more, diffusion can be prevented even more reliably.

To control the Peclet number Pe to a predetermined value for the purpose of preventing diffusion, it suffices, simply, to determine the type of the inert gas and control its flow rate. The diffusion coefficient D of the sublimate refers to the two-component diffusion coefficient of the sublimate and the inert gas. If the molecular weight of the inert gas differs, the diffusion coefficient D changes. The greater the molecular weight of the inert gas, the more difficult the diffusion of the sublimate becomes, and the higher the flow rate of the inert gas, the more difficult the diffusion of the sublimate becomes.

The inert gas refers to a gas inert to the sublimation reaction of the reaction product or to the material to be processed. Examples of the inert gas include argon, neon, xenon, and helium in addition to the above-mentioned nitrogen.

In the embodiment described above, prevention of diffusion through the second gas introducing ports 15 is not performed, but the diffusion of the sublimate may be prevented by introducing nitrogen through the second gas introducing ports 15 as well as through the first gas introducing ports 12.

The reason why the diffusion via the first gas introducing ports 12 is prevented is that since the first gas introducing ports 12 communicate with the first gas introducing path 11 provided with the plasma generating section 16, it is particularly preferred they not be contaminated with the sublimate or the like. In other words, by preventing the diffusion of the sublimate through the first gas introducing ports 12, contamination of the members constituting the first gas introducing path 11 provided with the plasma generating section 16 is prevented, the number of cleanings can be decreased, and the durability of the members can be enhanced, thus resulting in efficient low-cost processing.

As a third step, which is an optional step, it is permissible to etch away the surface (silicon layer) of the silicon substrate 5 deprived of the native oxide film, with the arrangement of the silicon substrates 5 deprived of the native oxide film being maintained, that is, in the same vacuum processing vessel 3, as has been described above. By this step, oxygen in the silicon surface as the interface of the oxide film, for example, oxygen which is likely to be present, say, in the metallic lattice of silicon, is removed, whereby the silicon substrates 5 having the surfaces reliably free from oxygen can be obtained. Furthermore, the silicon layer is etched using the apparatus for etching away the native oxide film. Thus, the silicon substrates 5 having high surface cleanliness can be obtained by very simple processing, without the occurrence of oxidation or the like due to transport.

The step of etching away the silicon layer after removal of the native oxide film will be described, as the third step, based on FIGS. 7 to 10.

As shown in FIG. 7, NH₃ gas and N₂ gas are introduced from the first gas introducing path 11, and H radicals H* and N radicals N* are generated in the plasma generating section 16. The resulting H radicals H* and N radicals N* are fed into the vacuum processing vessel 3 through the first gas introducing ports 12. Simultaneously, NF₃ gas is introduced into the vacuum processing vessel 3 through the second gas introducing ports 15 of the second shower nozzle 14. The surfaces of the silicon substrates 5 are etched away with the resulting radicals.

In the foregoing manner, oxygen in the silicon surface as the interface of the native oxide film is removed, and the silicon substrates 5 with the surfaces reliably deprived of oxygen can be obtained.

At this time, the silicon layer increases in the amount of etching in accordance with the etching time as indicated by squares □ in FIG. 9, whereas a layer other than the silicon layer (e.g., SiN) scarcely changes in the amount of etching with the passage of the etching time as indicated by triangles Δ in FIG. 9, showing that only the silicon layer is etched.

The status of introduction of the processing gases (NH₃ gas and N₂ gas, NF₃ gas) in the etching of the native oxide film and the etching of the silicon layer described above will be explained based on FIG. 10.

During the period from time t1 until time t2 (for example, 520 seconds), the processing gases are introduced (ON), while the lamp heater is turned off (OFF), whereby processing for reacting the precursor NHₓF_{y} with the native oxide film SiO₂ is performed (see FIGS. 4(a), 4(b)). During the period from the time t2 until time t3, the processing gases are stopped (OFF), whereas the lamp heater is turned on (ON), whereby the product (NH₄)₂SiF₆ is sublimated and the native oxide film SiO₂ is etched away (see FIGS. 4(c), 4(d)).

Then, during the period from the time t3 until time t4 (for example, 50 to 210 seconds), the processing gases are introduced again (ON). After the time t4, the lamp heater is turned on and off (ON/OFF), as appropriate, to maintain the temperature, whereby the silicon layer is etched away (see FIGS. 8(a), 8(b), 8(c)).

At the time t3, a cooling step for cooling the interior of the processing vessel can be carried out.

In the first embodiment, as described above, removal of the native oxide film and removal of the silicon layer deprived of the native oxide film can be performed within the same vacuum processing vessel 3. Thus, using the vacuum processing apparatus 1 for removing the native oxide film, oxygen at the interface of the silicon substrate 5 can be removed reliably, after removal of the native oxide film, in a short time by simple control. Hence, the silicon substrate 5 having a very high performance surface can be obtained by the vacuum processing apparatus 1 and the processing method which are simple.

The removal of the native oxide film and the removal of the silicon layer devoid of the native oxide film, which have been described above, are used to clean the bottom surface of a contact hole 31 of the semiconductor substrate, as shown in FIG. 11. That is, the native oxide film of the contact hole 31 is removed by the sublimation of (NH₄)₂SiF₆, whereafter the silicon layer is removed continuously. By this procedure, the contact hole 31 having the bottom surface reliably deprived of oxygen can be formed. When a wiring metal is then laminated thereon, wiring with very low resistance can be achieved.

In each of the foregoing embodiments, during etching of the silicon layer, NH₃ gas plus N₂ gas and NF₃ gas are introduced from the separate gas introducing means. However, this is not limitative, and all the gases may be introduced from the same gas introducing means having the plasma generating section.

In each of the foregoing embodiments, a so-called batch film-forming apparatus is described in which the plurality of substrates are arranged parallel to each other with predetermined spacing within the processing chamber. However, processing may be performed using a so-called single wafer apparatus in which substrates are disposed, one by one, within the processing chamber.

### TEST EXAMPLE

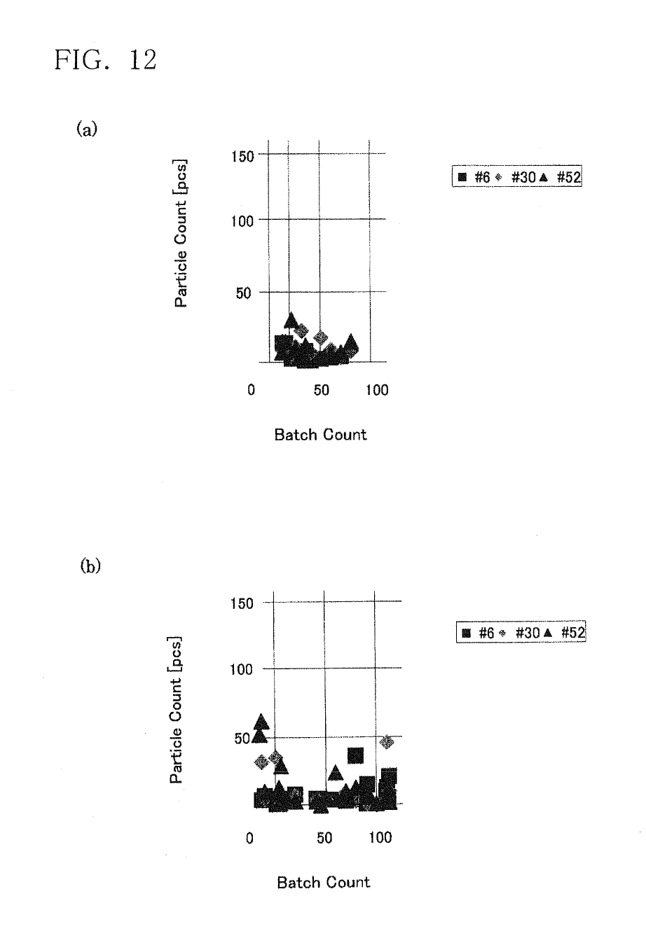

Using the vacuum processing apparatus according to the first embodiment, the first gas introducing paths 11 were renewed, and then batch processing of the silicon substrate was repeated for about 100 batches. Particles formed were counted, and the results are shown in FIG. 12(a). The particle count was made by sampling 3 of about 50 silicon substrates per batch processing, and counting the number of 0.2 μm or larger particles observed on each silicon substrate. The 3 silicon substrates are indicated by ▴, ▪ and ♦.

With the processing of FIG. 12(a), in the second step of etching, the first gas introducing means was allowed to function as the inert gas introducing means, and only N₂ gas was introduced at a flow rate of 2.0 L/min, with the plasma generating section 16 being stopped and the supply of NH₃ gas being stopped. By so doing, the sublimate was prevented from passing through the first gas introducing ports 12 and diffusing into the first shower nozzle 13 and the first gas introducing paths 11. The Peclet number Pe at this time can be estimated at 20.

On this occasion, only N₂ gas was introduced at a flow rate of 1.5 L/min from the second processing gas introducing ports as well.

For comparison, the results of processing of about 100 batches, with only N₂ gas being introduced at a flow rate of 20 L/min from the second processing gas introducing ports as well, are shown in FIG. 12(b).

### INDUSTRIAL APPLICABILITY

The present invention can be utilized in the industrial field of vacuum processing apparatuses for performing etching in a processing chamber in a vacuum state.

### EXPLANATION OF LETTERS OR NUMERALS

1 Vacuum processing apparatus

2 Charge/withdrawal vessel

3 Vacuum processing vessel

4 Turn table

5 Silicon substrate

6 Boat

7 Feed screw

8 Communicating port

9 Shutter means

10 Discharge section

11 First gas introducing path

12 First gas introducing port

13 First shower nozzle

14 Second shower nozzle

15 Second gas introducing port

16 Plasma generating section

17, 19 Flow regulating means

18 Second gas introducing path

31 Contact hole

1. A vacuum processing apparatus, comprising:
a processing chamber in which an object to be processed is placed and a predetermined vacuum state is formed;
first processing gas introducing means for converting a first processing gas into a radical state and introducing the resulting first processing gas in the radical state into the processing chamber through first processing gas introducing ports which open to an interior of the processing chamber;
second processing gas introducing means for introducing a second processing gas, which is reactive with the first processing gas in the radical state, into the processing chamber through second processing gas introducing ports which open to the interior of the processing chamber;
temperature controlling means for controlling a temperature within the processing chamber to a first temperature-controlled state, in which the first processing gas in the radical state and the second processing gas process a surface of the object to be processed, thereby producing a reaction product, and to a second temperature-controlled state in which the resulting reaction product is sublimated and removed; and
inert gas introducing means for introducing an inert gas into the processing chamber through the first processing gas introducing ports when the temperature controlling means controls the temperature within the processing chamber to the second temperature-controlled state.

2. The vacuum processing apparatus according to claim 1, wherein
the inert gas introducing means is equipped with introduction controlling means for controlling an introduction status of the inert gas through the first processing gas introducing ports so as to prevent a sublimate of the reaction product from passing and diffusing through the processing gas introducing ports.

3. The vacuum processing apparatus according to claim 2, wherein
the introduction controlling means controls the introduction status of the inert gas such that a Peclet number representing a state of a difference between an introduction flux of the inert gas introduced and a diffusion flux of the sublimate of the reaction product becomes 10 or more.

4. The vacuum processing apparatus according to claim 1, wherein
the inert gas introducing means is adapted to introduce the inert gas via the first gas introducing means.

5. The vacuum processing apparatus according to claim 1, wherein
the first gas introducing means is adapted to equip a first gas introducing path, which communicates with the first gas introducing ports, with a plasma generating section, and convert the introduced first processing gas into a plasma state in the plasma generating section.

6. The vacuum processing apparatus according to claim 1, wherein
the first processing gas is a gas for generating H radicals,
the second processing gas is a gas for generating at least NHₓF_{y}, and
the object to be processed is a silicon substrate.

7. The vacuum processing apparatus according to claim 6, wherein
the first processing gas is at least one of NH₃ and H₂ and N₂, and
the second processing gas is NF₃.

8. The vacuum processing apparatus according to claim 6, further comprising
auxiliary gas introducing means for introducing an auxiliary processing gas in a radical state into the processing chamber, and
control means for controlling an introduction status of the auxiliary processing gas introduced from the auxiliary gas introducing means and the second processing gas introduced from the second gas introducing means, thereby removing a surface layer of the silicon substrate, which has been deprived of a native oxide film by processing with the processing gases, by a predetermined thickness by the auxiliary processing gas and the second processing gas.

9. The vacuum processing apparatus according to claim 8, wherein
the first gas introducing means concurrently serves as the auxiliary gas introducing means.

10. The vacuum processing apparatus according to claim 8, wherein
the control means applies the auxiliary processing gas and the second processing gas to a surface of the silicon substrate deprived of the native oxide film, thereby removing a silicon layer of the silicon substrate by the predetermined thickness.

11. A vacuum processing method, comprising:
introducing a first processing gas in a radical state into a processing chamber, in which an object to be processed is placed and a predetermined vacuum state is formed, through first processing gas introducing ports, and also introducing a second processing gas, which is reactive with the first processing gas in the radical state, into the processing chamber through second processing gas introducing ports; and
controlling a temperature within the processing chamber to a first temperature-controlled state, in which the first processing gas in the radical state and the second processing gas process a surface of the object to be processed, thereby producing a reaction product, and then to a second temperature-controlled state in which the resulting reaction product is sublimated and removed, while introducing an inert gas into the processing chamber through the first processing gas introducing ports when controlling the temperature within the processing chamber to the second temperature-controlled state.
